(19) United States
(12) Patent Application Publication
(10) Pub. No.: US 2026/0324452 A1
(43) Pub. Date: Oct. 15, 2026

(54) POWER MODULE AND METHOD OF MANUFACTURING POWER MODULE

(71) Applicants: Hyundai Motor Company, Seoul (KR); Kia Corporation, Seoul (KR)

(72) Inventors: Se Yoon JEONG, Hwaseong-si (KR); Sung Taek HWANG, Hwaseong-si (KR); Sung Won PARK, Hwaseong-s (KR); Nam Sik KONG, Hwaseong-si (KR)

(73) Assignees: Hyundai Motor Company, Seoul (KR); Kia Corporation, Seoul (KR)

(21) Appl. No.: 19/306,061

(22) Filed: Aug. 21, 2025

(30) Foreign Application Priority Data
Apr. 9, 2025 (KR) 10-2025-0046266

(51) Int. Cl. H10W 70/40; H10W 40/25; H10W 70/60; H10W 70/65; H10W 74/10; H10W 90/00

(52) U.S. Cl. CPC H10W 70/421; H10W 40/255; H10W 70/466; H10W 70/611; H10W 70/65; H10W 74/111; H10W 90/734

(57) ABSTRACT

A power module includes a main substrate, at least one chip disposed on the substrate board, an interconnection substrate connected to one surface of the chip, not opposing the main substrate, and a lead portion connected to the interconnection substrate and configured to supply power to the chip or apply a control signal to the chip.

### CROSS-REFERENCE TO RELATED APPLICATIONS

The present application claims benefit of priority to Korean Patent Application No. 10-2025-0046266 filed on Apr. 9, 2025 in the Korean Intellectual Property Office, the disclosure of which is incorporated herein by reference in its entirety.

### TECHNICAL FIELD

The present disclosure relates to a power module and a method of manufacturing the same.

Recently, with growing interest in environment issues, the number of eco-friendly vehicles equipped with electric motors as power sources has increased. Eco-friendly vehicles, also referred to as electric vehicles, may include, as representative examples, electric vehicles (EVs) and hybrid electric vehicles (HEVs). An inverter for power control may be used as a core component significantly affecting the performance and efficiency of such vehicles.

An inverter, a device converting direct current (DC) power into alternating current (AC) power, may receive power from a high-voltage battery to drive an electric motor. The inverter may include a power module as a core component. The power module may perform power conversion by handling high voltages and currents.

The power module may include a substrate, a semiconductor chip, a power lead, and a signal lead. The semiconductor chip may be surrounded by a molded portion. One end portion of the power lead may be connected to the semiconductor chip within the molded portion to supply power to the semiconductor chip. In addition, power converted by the semiconductor chip may be output through the power lead. One end portion of the signal lead may be connected to the semiconductor chip in the molded portion to apply a control signal to the chip or receive state information from the chip.

### SUMMARY

An aspect of the present disclosure is to provide a power module configured for simplifying a manufacturing process, and a method of manufacturing the same.

Another aspect of the present disclosure is to provide a power module facilitating securing a heat dissipation area, the power module applicable to various specifications, and a method of manufacturing the same.

Another aspect of the present disclosure is to provide a power module configured for reducing manufacturing costs and easily securing internal space.

Another aspect of the present disclosure is to provide a power module configured for preventing solder overflow during manufacturing, and a method for manufacturing the same.

According to an aspect of the present disclosure, there is provided a power module including a main substrate, at least one chip disposed on the substrate board, an interconnection substrate connected to one surface of the chip, not opposing the main substrate, and a lead portion connected to the interconnection substrate and configured to supply power to the chip or apply a control signal to the chip.

According to another aspect of the present disclosure, there is provided a method of manufacturing a power module, the method including a chip mounting operation of mounting a chip on a main substrate, a circuit pattern forming operation of forming a circuit pattern on the main substrate, an interconnection substrate bonding operation of bonding an interconnection substrate to the chip and the main substrate, a lead portion bonding operation of bonding a lead portion to the main substrate and the interconnection substrate, and a molded portion forming operation of forming a molded portion to cover the chip and the interconnection substrate.

According to example embodiments of the present disclosure, a power module may simplify a manufacturing process.

According to example embodiments of the present disclosure, a power module may facilitate securing a heat dissipation area, and may be applicable to various specifications

According to example embodiments of the present disclosure, a power module may reduce manufacturing costs and easily secure internal space.

According to example embodiments of the present disclosure, a power module may prevent solder overflow during manufacturing.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view of a power module according to an exemplary embodiment of the present disclosure from which a molded portion is removed;

FIG. 2 is a partial plan view of a power module according to an exemplary embodiment of the present disclosure from which a molded portion is removed;

FIG. 3 is an exploded perspective view of a main substrate and an interconnection substrate in a power module according to an exemplary embodiment of the present disclosure;

FIG. 4 is a cross-sectional view taken along line A-A’ of FIG. 1;

FIG. 5 is a cross-sectional view taken along line B-B’ of FIG. 1;

FIG. 6 is a flowchart of a method of manufacturing a power module according to another exemplary embodiment of the present disclosure;

FIG. 7 is a perspective view of a main substrate;

FIG. 8 is a perspective view of a main substrate after a preform process is completed;

FIG. 9 is a plan view of an interconnection substrate; and

FIG. 10 is a plan view of a state in which a lead portion and an interconnection substrate are bonded to a main substrate.

### DETAILED DESCRIPTION

Various modifications may be made to the example embodiments. Here, the example embodiments are not construed as limited to the disclosure and should be understood to include all changes, equivalents, and replacements within the idea and the technical scope of the disclosure.

The terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component. The term “and/or” may include combinations of a plurality of related described items or any of a plurality of related described items.

The terms such as “unit,” “portion,” “part,” and the like may be used to describe various components, but the components should not be limited by the terms. The above-described terms may refer to a term indicating not only a physically/visually distinct component, but also a function or component of a corresponding portion even when not clearly divided or partitioned.

The terminology used herein is for the purpose of describing particular example embodiments only and is not to be limiting of the example embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in the present disclosure, specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein, including technical or scientific terms, have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

In the description below, the terms “front,” “rear,” “upper,” “lower,” “top,” “bottom,” and the like used in relation to directions are defined based on the drawings.

Hereinafter, exemplary embodiments of the present disclosure will be described in more detail with reference to the accompanying drawings.

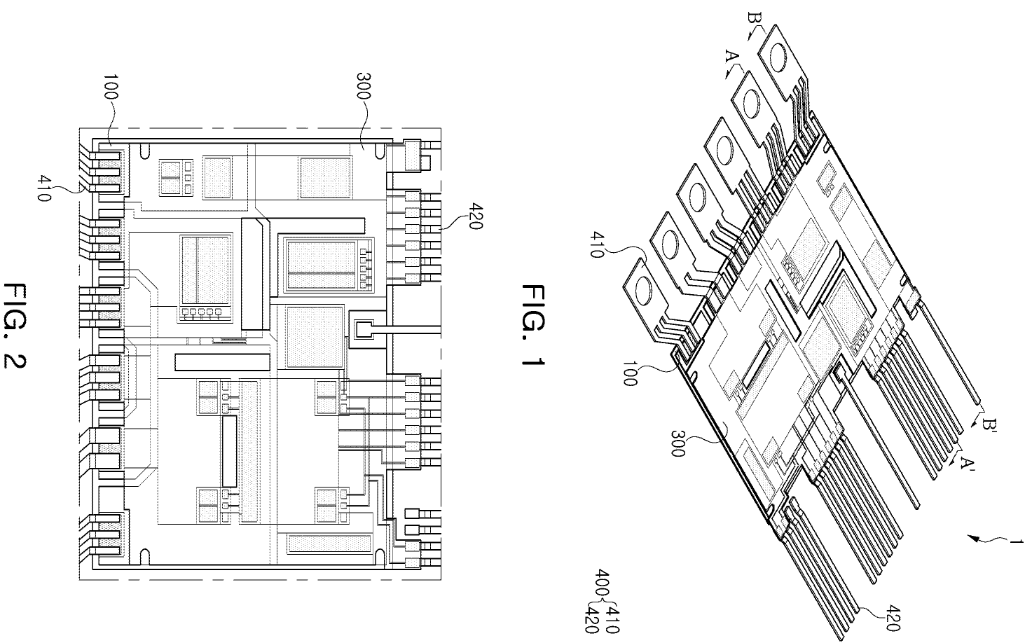

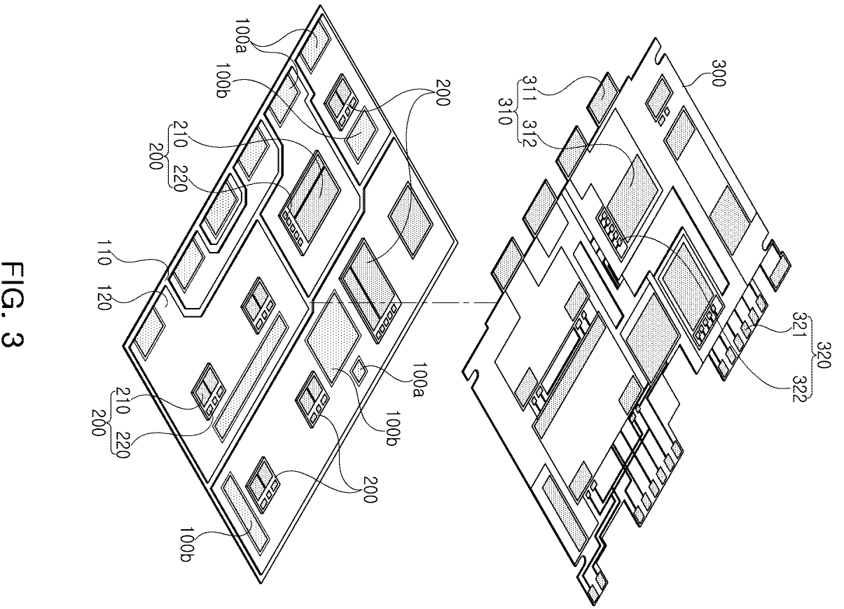

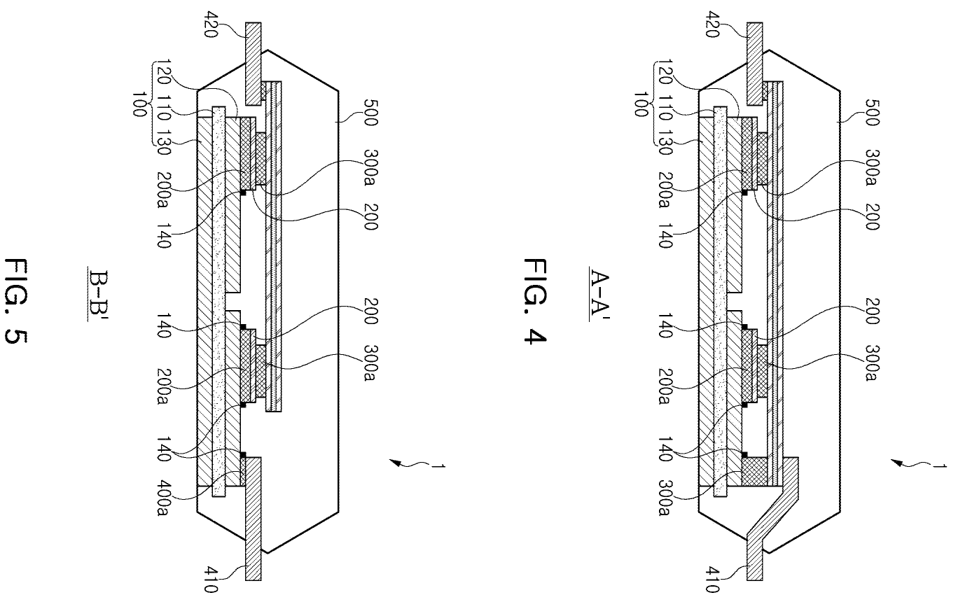

FIG. 1 is a perspective view of a power module according to an exemplary embodiment of the present disclosure from which a molded portion is removed. FIG. 2 is a partial plan view of a power module according to an exemplary embodiment of the present disclosure from which a molded portion is removed. FIG. 3 is an exploded perspective view of a main substrate and an interconnection substrate in a power module according to an exemplary embodiment of the present disclosure. FIG. 4 is a cross-sectional view taken along line A-A’ of FIG. 1. FIG. 5 is a cross-sectional view taken along line B-B’ of FIG. 1.

Referring to FIGS. 1 to 5, a power module 1 according to an exemplary embodiment of the present disclosure may include a main substrate 100, a chip 200, an interconnection substrate 300, and a lead portion 400.

The main substrate 100 may be provided as an insulating substrate. The main substrate 100 may include a plurality of circuit lines. The circuit line may be a circuit pattern. The main substrate 100 may include, for example, an insulating layer 110, a first metal layer 120, and a second metal layer 130.

The insulating layer 110 may include at least one of ceramic or a polymer resin. For example, the insulating layer 110 may include at least one of alumina, aluminum nitride, silicon nitride, epoxy, or polyimide. The insulating layer 110 may be disposed on the inside of a molded portion 500. The insulating layer 110 may be disposed, for example, in a form of a plate.

The first metal layer 120 may be disposed on one surface of the insulating layer 110. The first metal layer 120 may be disposed on the inside of the molded portion 500. The first metal layer 120 may include a plurality of circuit lines. The circuit lines of the first metal layer 120 may refer to circuit patterns. The circuit lines of the first metal layer 120 may be connected to at least one of a power lead 410 or a signal lead 420. The first metal layer 120 may be provided as a conductor having high electrical conductivity. For example, the first metal layer 120 may include at least one of copper, aluminum, silver, or nickel. The first metal layer 120 may be formed using a lamination, deposition, or plating method. The method of forming the first metal layer 120 may be replaced by various methods commonly used in the technical field to which the present disclosure pertains.

The second metal layer 130 may be disposed on the other surface of the insulating layer 110. At least a portion of the second metal layer 130 may be exposed to the outside of the molded portion 500. A cooler may be connected to the portion of the second metal layer 130 exposed to the outside of the molded portion 500. When the chip 200 disposed on the substrate 100 operates, heat may be generated. The heat generated in the chip 200 may be transferred to the second metal layer 130. The heat generated in the chip 200 may be dissipated externally through the second metal layer 130. The second metal layer 130 may be provided as a conductor having high thermal conductivity. For example, the second metal layer 130 may include at least one of copper or aluminum. The second metal layer 130 may be formed using a lamination, deposition, or plating method. The method of forming the second metal layer 130 may be replaced by various methods commonly used in the technical field to which the present disclosure pertains.

The chip 200 may be disposed on one surface of the main substrate 100. For example, the chip 200 may be disposed on the first metal layer 120 of the main substrate 100. A chip solder layer 200a may be disposed between the chip 200 and the first metal layer 120 according to bonding of the chip 200. The chip 200 may be electrically connected to the first metal layer 120.

The chip 200 may include, for example, at least one of an insulated gate bipolar transistor (IGBT), a compound semiconductor (SiC), a classifier circuit, a silicon-controlled rectifier (SCR), a power transistor, a MOS transistor, a power rectifier, a power regulator, or a diode. The chip 200 may be a switching device. Conversion with respect to input power may be performed by a switching operation of the chip 200. For example, the chip 200 may convert DC power to AC power or convert AC power to DC power.

The chip 200 may include a power pad 210 and a signal pad 220. The power pad 210 may be electrically connected to the power lead 410, and the signal pad 220 may be electrically connected to the signal lead 420. For example, the power pad 210 may be connected to the power lead 410 through the interconnection substrate 300, and the signal pad 220 may be connected to the signal lead 420 through the interconnection substrate 300.

The interconnection substrate 300 may be disposed on the inside of the molded portion 500. The interconnection substrate 300 may be connected to the chip 200. The interconnection substrate 300 may electrically connect the chip 200 and the lead portion 400 to each other. The interconnection substrate 300 may be connected to one surface of the chip 200, not opposing the main substrate 100. The interconnection substrate 300 may be provided, for example, as a printed circuit board (PCB) or a flexible printed circuit board (FPCB). The interconnection substrate 300 may include a high-current circuit pattern 310 and a low-current circuit pattern 320. The high-current circuit pattern 310 may be electrically connected to the power lead 410 and the power pad 210 of the chip 200. The low-current circuit pattern 320 may be electrically connected to the signal lead 420 and the signal pad 220 of the chip 200. The interconnection substrate 300 may electrically connect the chip 200 and the lead portion 400 to each other. For example, the high-current circuit pattern 310 may electrically connect the chip 200 and the power lead 410 to each other, and the low-current circuit pattern 320 may electrically connect the chip and the signal lead 420 to each other. Through the high-current circuit pattern 310, power of the power lead 410 may be input to the chip 200, or power converted by the chip 200 may be output to the power lead 410. Through the low-current circuit pattern 320, a control signal of the signal lead 420 may be transmitted to the chip 200, or state information of the chip 200 may be transmitted to the signal lead 420.

The high-current circuit pattern 310 may include, for example, a power lead bonding portion 311 to which the power lead 410 is bonded and a power pad bonding portion 312 electrically connected to the power lead bonding portion 311 and bonded to the power pad 210 of the chip 200. At least one power lead bonding portion 311 may be disposed on, for example, one edge portion of the interconnection substrate 300.

The low-current circuit pattern 320 may include, for example, a signal lead bonding portion 321 to which a signal lead 420 is bonded, and a signal pad bonding portion 322 electrically connected to the signal lead bonding portion 321 and bonded to the signal pad 220 of the chip 200. At least one signal lead bonding portion 321 may be disposed on the other edge portion of the interconnection substrate 300. Positions at which the power lead bonding portion 311 and the signal lead bonding portion 321 are provided in the interconnection substrate 300 may be changed depending on a design of the power module 1.

At least a portion of the interconnection substrate 300 may be bonded to the main substrate 100. An interconnection substrate solder layer 300a according to bonding of the interconnection substrate 300 may be disposed between the interconnection substrate 300 and the main substrate 100.

The chip 200 and the lead portion 400 may be connected to each other using the interconnection substrate 300, simplifying or partially omitting a circuit pattern of the main substrate 100. As a result, a heat dissipation area of the main substrate 100 may be increased. Furthermore, wire bonding that has been used for connection between a chip and a lead portion in the related art may be omitted using the interconnection substrate 300, simplifying a manufacturing process. Furthermore, issues, such as wire cracks or wire delamination occurring during wire bonding of a chip, may be resolved, improving reliability of a product.

The lead portion 400 may be connected to the interconnection substrate 300 to supply power to the chip 200 or apply a control signal to the chip 200. The lead portion 400 may include, for example, the power lead 410 and the signal lead 420.

The power lead 410 may be provided to supply power to the chip 200 or to output power converted by the chip 200. One end portion of the power lead 410 may be electrically connected to the chip 200 within the molded portion 500. The other end portion of the power lead 410 may be exposed to the outside of the molded portion 500. The power lead 410 may be electrically connected to the chip 200 through the interconnection substrate 300. The power lead 410 may be provided as a plurality of power leads 410. A portion of the plurality of power leads 410 may be connected to the interconnection substrate 300. For example, some power leads, among the plurality of power leads 410, may be bonded to the power lead bonding portion 311 of the interconnection substrate 300. Remaining power leads 410 not connected to the interconnection substrate 300, among the plurality of power leads 410, may be connected to the main substrate 100.

The signal lead 420 may be provided to input a control signal to the chip 200 or to receive state information of the chip 200. One end portion of the signal lead 420 may be electrically connected to the chip 200 within the molded portion 500. The other end portion of the signal lead 420 may be exposed to the outside of the molded portion 500. The signal lead 420 may be electrically connected to the chip 200 through the interconnection substrate 300. The signal lead 420 may be provided as a plurality of signal leads 420. A portion of the plurality of signal leads 420 may be connected to the interconnection substrate 300. For example, some signal leads, among the plurality of signal leads 420, may be bonded to the signal lead bonding portion 312 of the interconnection substrate 300. Remaining signal leads 420 not connected to the interconnection substrate 300, among the plurality of signal leads 420, may be connected to the main substrate 100.

A photosensitive solder resist layer 140 may be disposed on the main substrate 100. The photosensitive solder resist layer 140 may be disposed, for example, along at least a portion of edge portions of the chip solder layer 200a, the interconnection substrate solder layer 300a, and a lead portion solder layer 400a.

The chip solder layer 200a may bond the chip 200 to the main substrate 100, and the interconnection substrate solder layer 300a may bond the interconnection substrate 300 to the main substrate 100. The lead portion solder layer 400a may bond the lead portion 400 to the main substrate 100. When the chip 200, the interconnection substrate 300, and the lead portion 400 are bonded to the main substrate 100, that is, during formation of the chip solder layer 200a, the interconnection substrate solder layer 300a, and the lead portion solder layer 400a, the photosensitive solder resist layer 140 may prevent solder from overflowing to a region other than a designated region or formation of an unnecessary solder bridge.

The molded portion 500 may form an external periphery of the power module 1. The molded portion 500 may protect the chip 200 from external moisture or impact. The molded portion 500 may improve bonding strength between the main substrate 100, the chip 200, the interconnection substrate 300, and the lead portion 400. The molded portion 500 may be provided using, for example, engineering plastic or an epoxy molding compound (EMC). A portion of each of the power lead 410 and the signal lead 420 may be exposed to the outside of the molded portion 500. At least a portion of the second metal layer 130 of the main substrate 100 may be exposed to the outside of the molded portion 500.

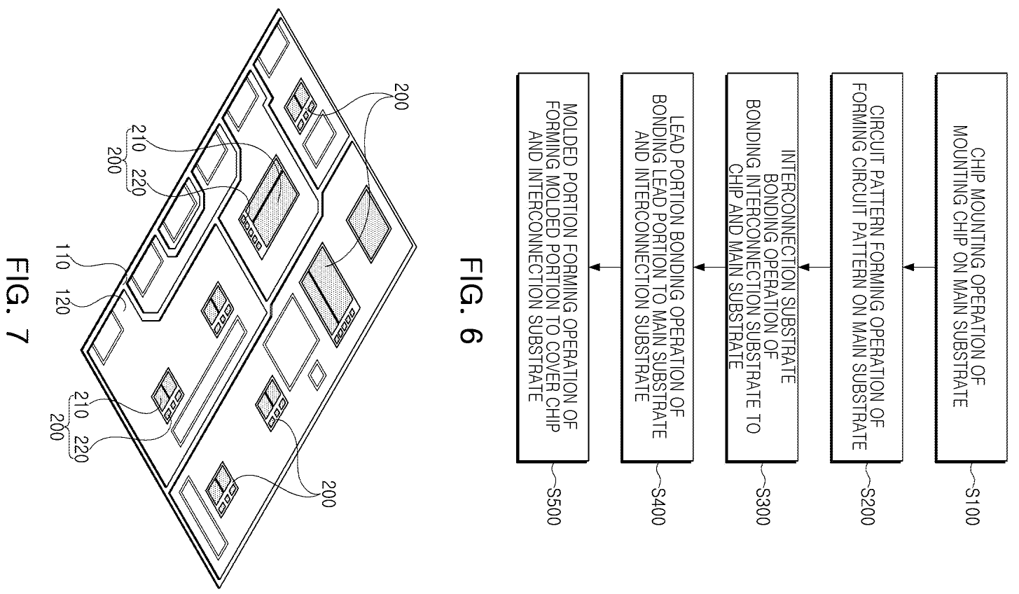

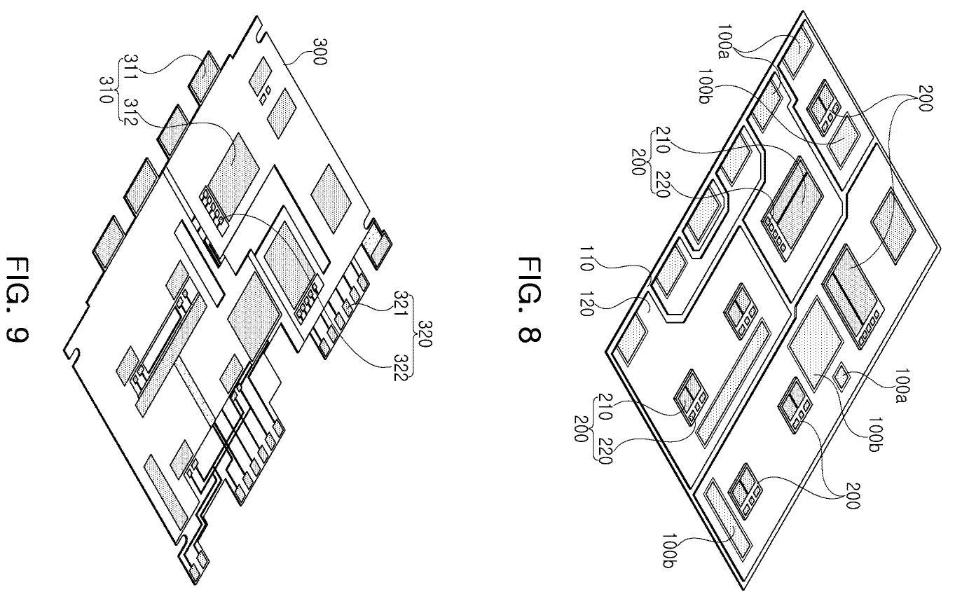

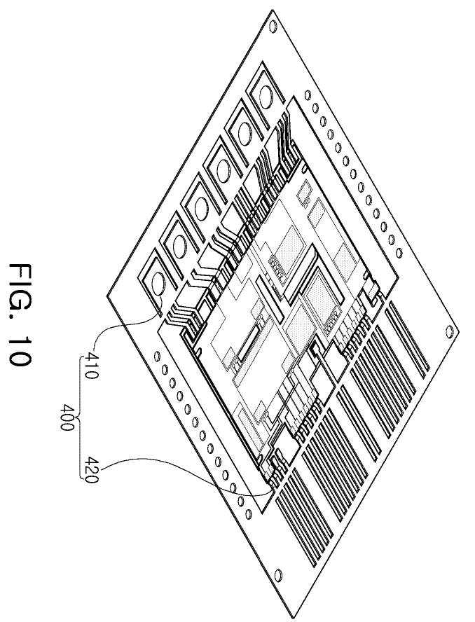

FIG. 6 is a flowchart of a method of manufacturing a power module according to another exemplary embodiment of the present disclosure. FIG. 7 is a perspective view of a main substrate. FIG. 8 is a perspective view of a main substrate after a preform process is completed. FIG. 9 is a plan view of an interconnection substrate. FIG. 10 is a plan view of a state in which a lead portion and an interconnection substrate are bonded to a main substrate.

Referring to FIGS. 6 to 10, the method of manufacturing a power module according to another exemplary embodiment of the present disclosure may include a chip mounting operation (S100), a circuit pattern forming operation (S200), an interconnection substrate bonding operation (S300), a lead portion bonding operation (S400), and a molded portion forming operation (S500).

Referring to FIG. 7, in the chip mounting operation (S100), at least one chip 200 may be disposed on a main substrate 100. A photosensitive solder resist layer 140 may be disposed on the main substrate 100. The chip 200 may be disposed on the main substrate 100 using, for example, a sintering or soldering method. For example, the chip 200 may be disposed on a first metal layer 120 of the main substrate 100. A chip solder layer 200a according to bonding of the chip 200 may be disposed between the chip 200 and the first metal layer 120. The chip 200 may include a power pad 210 and a signal pad 220.

Referring to FIG. 8, in the circuit pattern forming operation (S200), an electrode circuit pattern 100a may be formed on the main substrate 100. The electrode circuit pattern 100a may be an electrode to which a lead portion 400 is electrically connected. The lead portion 400 may be directly connected to a portion of the electrode circuit pattern 100a, and indirectly connected to a remaining portion of the electrode circuit pattern 100a through an interconnection substrate 300. In addition, in the circuit pattern forming operation (S200), a spacer 100b may be formed. The spacer 100b may have both end portions connected to the main substrate 100 and the interconnection substrate 300, and thus may electrically connect the main substrate 100 and the interconnection substrate 300 to each other.

Referring to FIG. 9, in the interconnection substrate bonding operation (S300), the interconnection substrate 300 may be bonded to the chip 200 and the main substrate 100. The interconnection substrate 300 may include a high-current circuit pattern 310 and a low-current circuit pattern 320. The high-current circuit pattern 310 may include, for example, a power lead bonding portion 311 to which a power lead 410 is bonded, and a power pad bonding portion 312 electrically connected to the power lead bonding portion 311 and bonded to the power pad 210 of the chip 200. The power lead bonding portion 311 may be disposed, for example, on one edge portion of the interconnection substrate 300.

The low-current circuit pattern 320 may include, for example, a signal lead bonding portion 321 to which a signal lead 420 is bonded, and a signal pad bonding portion 322 electrically connected to the signal lead bonding portion 321 and bonded to the signal pad 220 of the chip 200. The signal lead bonding portion 321 may be disposed, for example, on the other edge portion of the interconnection substrate 300. Positions in the interconnection substrate 300 at which the power lead bonding portion 311 and the signal lead bonding portion 321 are provided may be changed depending on a design of the power module 1.

At least a portion of the interconnection substrate 300 may be bonded to the main substrate 100. An interconnection substrate solder layer 300a according to bonding of the interconnection substrate 300 may be disposed between the interconnection substrate 300 and the main substrate 100.

Referring to FIG. 10, in the lead portion bonding operation (S400), the lead portion 400 may be bonded to the main substrate 100 and the interconnection substrate 300. The lead portion 400 may be connected to the main substrate 100 and the interconnection substrate 300 to supply power to the chip 200 or apply a control signal. The lead portion 400 may include, for example, the power lead 410 and the signal lead 420.

After bonding of the lead portion 400 is completed, the molded portion forming operation (S500) may be performed. The molded portion 500 may form an external periphery of the power module. The molded portion 500 may be provided using, for example, engineering plastic or EMC. A portion of each of the power lead 410 and the signal lead 420 may be exposed to the outside of the molded portion 500. At least a portion of a second metal layer 130 of the main substrate 100 may be exposed to the outside of the molded portion 500.

While example embodiments have been shown and described above, it will be apparent to those skilled in the art that modifications and variations could be made without departing from the scope of the present disclosure as defined by the appended claims.

What is claimed is:

1. A power module comprising:
a main substrate;
at least one chip disposed on the substrate board;
an interconnection substrate connected to one surface of the at least one chip, not opposing the main substrate; and
a lead portion connected to the interconnection substrate and configured to supply power to the at least one chip or apply a control signal to the at least one chip.

2. The power module of claim 1, wherein the lead portion includes:
at least one power lead connected to the main substrate or the interconnection substrate to supply the power to the at least one chip; and
a signal lead connected to the main substrate or the interconnection substrate to input the control signal to the at least one chip or to receive state information of the at least one chip.

3. The power module of claim 2,
wherein the power lead is provided as a plurality of power leads, a predetermined number of power leads among the power leads, are connected to the interconnection substrate and remaining power leads among the power leads, are connected to the main substrate, and
wherein the signal lead is provided as a plurality of signal leads, a predetermined number of signal leads among the signal leads, are connected to the interconnection substrate, and remaining signal leads among the signal leads, are connected to the main substrate.

4. The power module of claim 2, wherein the interconnection substrate includes:
a high-current circuit pattern connected to the power lead and a power pad of the at least one chip; and
a low-current circuit pattern connected to the signal lead and a signal pad of the at least one chip.

5. The power module of claim 4,
wherein the high-current circuit pattern includes:
a power lead bonding portion to which the power lead is bonded; and
a power pad bonding portion electrically connected to the power lead bonding portion and bonded to the power pad of the at least one chip, and
wherein the low-current circuit pattern includes:
a signal lead bonding portion to which the signal lead is bonded; and
a signal pad bonding portion electrically connected to the signal lead bonding portion and bonded to the signal pad of the at least one chip.

6. The power module of claim 5,
wherein the power lead bonding portion is disposed on a first edge portion of the interconnection substrate, and
wherein the signal lead bonding portion is disposed on a second edge portion of the interconnection substrate.

7. The power module of claim 1, further comprising:
a molded portion in which the at least one chip and the interconnection substrate are disposed, and
at least a portion of one surface of the main substrate on which the at least one chip is not mounted is exposed to an outside of the molded portion.

8. The power module of claim 7, wherein the main substrate includes:
an insulating layer;
a first metal layer disposed on a first surface of the insulating layer, the first metal layer disposed on an inside of the molded portion; and
a second metal layer disposed on a second surface of the insulating layer, the second metal layer including at least a portion exposed to the outside of the molded portion.

9. The power module of claim 1, wherein the interconnection substrate is disposed as a printed circuit board (PCB) or a flexible printed circuit board (FPCB).

10. The power module of claim 1, wherein the main substrate includes a photosensitive solder resist layer.

11. The power module of claim 10, further comprising:
a chip solder layer bonding the at least one chip to the main substrate; and
an interconnection substrate solder layer bonding the interconnection substrate to the main substrate,
wherein the photosensitive solder resist layer is disposed along at least a portion of edge portions of the at least one chip solder layer and the interconnection substrate solder layer.

12. The power module of claim 10, further comprising:
a lead portion solder layer bonding the lead portion to the main substrate.

13. The power module of claim 12, wherein the photosensitive solder resist layer is disposed along at least a portion of an edge portion of the lead portion solder layer.

14. A method of manufacturing a power module, the method comprising:
a chip mounting operation of mounting a chip on a main substrate;
a circuit pattern forming operation of forming a circuit pattern on the main substrate;
an interconnection substrate bonding operation of bonding an interconnection substrate to the chip and the main substrate;
a lead portion bonding operation of bonding a lead portion to the main substrate and the interconnection substrate; and
a molded portion forming operation of forming a molded portion to cover the chip and the interconnection substrate.

15. The method of claim 14, wherein
in the interconnection substrate bonding operation, the interconnection substrate includes a high-current circuit pattern and a low-current circuit pattern,
the high-current circuit pattern is connected to a power pad of the chip and a power lead of the lead portion, and
the low-current circuit pattern is connected to a signal pad of the chip and a signal lead of the lead portion.

16. The method of claim 15,
wherein the high-current circuit pattern includes a power lead bonding portion to which the power lead is bonded, and a power pad bonding portion electrically connected to the power lead bonding portion and bonded to the power pad of the chip, and
wherein the low-current circuit pattern includes a signal lead bonding portion to which the signal lead is bonded, and a signal pad bonding portion electrically connected to the signal lead bonding portion and bonded to the signal pad of the chip.

17. The method of claim 16,
wherein the power lead bonding portion is disposed on a first edge portion of the interconnection substrate, and
wherein the signal lead bonding portion is disposed on a second edge portion of the interconnection substrate.
